(19) United States
(12) Patent Application Publication
(10) Pub. No.: US 2024/0304595 A1
(43) Pub. Date: Sep. 12, 2024

(54) SEMICONDUCTOR CHIP HAVING A FRICTION STRUCTURE, SEMICONDUCTOR PACKAGE INCLUDING THE SAME, AND METHOD FOR MANUFACTURING A SEMICONDUCTOR PACKAGE

(71) Applicant: SAMSUNG ELECTRONICS CO., LTD, Suwon-Si (KR)

(72) Inventor: LEE DONGKUK, Suwon-si (KR)

(21) Appl. No.: 18/521,965

(22) Filed: Nov. 28, 2023

(30) Foreign Application Priority Data
Mar. 7, 2023 (KR) 10-2023-0030037

(51) Int. Cl. H01L 23/00; H01L 23/498; H01L 25/065

(52) U.S. Cl. CPC H01L 24/81; H01L 23/49822; H01L 24/05; H01L 25/0657; H01L 2224/05024; H01L 2224/051; H01L 2224/056; H01L 2224/81203; H01L 2225/06517; H01L 2924/15311

(57) ABSTRACT

A semiconductor chip includes a plurality of metal pads provided on a first surface of the semiconductor chip and defining a first area, a plurality of bumps provided on the plurality of metal pads, and a friction structure provided at least a portion of the first area near a corner of the first surface.

### CROSS-REFERENCE TO RELATED APPLICATION

This application claims priority under 35 U.S.C. § 119 to Korean Patent Application No. 10-2023-0030037, filed in the Korean Intellectual Property Office on Mar. 7, 2023, the entire contents of which are herein incorporated by reference.

### BACKGROUND

### (a) Technical Field

The present disclosure relates to a semiconductor chip having a friction structure on a surface facing another semiconductor chip, and a semiconductor package including the same, and a method for manufacturing a semiconductor package.

### (b) Discussion of Related Art

Semiconductor manufacturing processes may include a packaging process. The packaging process may include cutting a semiconductor wafer into a plurality of semiconductor chips, bonding the chips to a substrate, and encapsulation of the chips.

3D packaging technology is an integration technology that vertically stacks two or more semiconductor chips. That is, one semiconductor chip may be attached on another semiconductor chip. The semiconductor chips may be electrically connected to the outside through wire bonding, for example.

By using a through-silicon via (TSV), a top semiconductor chip of a 3D package may be electrically connected to the outside through the TSV of the bottom semiconductor chip. That is, by using TSV connections, wire bonding between the top semiconductor chip and the package substrate may not be required. In a packaging using TSV connections, the package may be further down-sized and the performance of the package may be improved.

A conventional 3D packaging process for attaching two semiconductor chips is described with reference to the drawings. FIG. 1A, FIG. 1B and FIG. 1C show a process of attaching a top semiconductor chip 100 to a bottom semiconductor chip 200.

Referring to FIG. 1A, a plurality of bumps 110 may be provided on a surface of the top semiconductor chip 100. The plurality of bumps 110 may be provided on metal pads. The metal pads may be electrically connected to semiconductor elements in the top semiconductor chip 100. A non-conductive film material NCF covers the plurality of bumps 110. The non-conductive film material NCF may serve to insulate bumps and bond two chips between the top semiconductor chip 100 and the bottom semiconductor chip 200. Metal pads 210 may be provided on a first surface of the bottom semiconductor chip 200.

Referring to FIG. 1B, the top semiconductor chip 100 may be aligned with the bottom semiconductor chip 200 by the thermal compression tool TC. The thermal compression tool TC may apply heat and pressure to the top semiconductor chip 100. The non-conductive film material NCF may be melted into a gel state, and the plurality of bumps 110 may be aligned on the metal pad 210.

Referring to FIG. 1C, the plurality of bumps 110 may penetrate the molten non-conductive film material NCF and may be electrically connected to a metal pad 210. A space between the top semiconductor chip 100 and the bottom semiconductor chip 200 may be filled with the non-conductive film material NCF, and thereby insulation between the plurality of bumps 110 may be achieved. A part of the molten non-conductive film material NCF may be pushed out around the top semiconductor chip 100.

FIG. 2A, FIG. 2B, FIG. 2C, and FIG. 2D show a planar change of the non-conductive film material during the conventional process of FIGS. 1A-D.

FIG. 2A shows the plurality of bumps 110 provided on a surface of the top semiconductor chip 100. FIG. 2B shows the non-conductive film material NCF attached to the surface of the top semiconductor chip 100 to cover the plurality of bumps 110. FIG. 2C shows the contracted non-conductive film material NCF. When heated, the non-conductive film material NCF may turn into a gel-like state, and may be agglomerated to the center by surface tension. In particular, a corner portion of the non-conductive film material NCF may having a curved shape, and the entire non-conductive film material NCF may shrink away from edges of the top semiconductor chip 100. FIG. 2D shows a planar distribution of the non-conductive film material NCF when the top semiconductor chip 100 is completely attached to the bottom semiconductor chip 200. When the top semiconductor chip 100 is pressed toward the bottom semiconductor chip 200, a portion of the non-conductive film material NCF may be pushed out to the sides. However, the non-conductive film material NCF may not entirely expand to the corners due to surface tension. As a result, the corner area of the top semiconductor chip 100 may not be sufficiently filled with the non-conductive film material NCF, and the adhesion between the top semiconductor chip 100 and the bottom semiconductor chip 200 may be weakened. Also, among the plurality of bumps 110, some bumps disposed near corners may not be sufficiently protected by the non-conductive film material NCF.

### SUMMARY

The present disclosure attempts to provide a means to ensure that a non-conductive material fills over an entire attachment region between semiconductor chips by suppressing a contractive movement of a non-conductive film material NCF when a semiconductor chip is attached to a surface of another semiconductor chip.

According to a first aspect of present disclosure, a semiconductor chip is provided. The semiconductor chip includes a plurality of metal pads provided on a first surface of the semiconductor chip and defining a first area, a plurality of bumps provided on the plurality of metal pads, and a friction structure provided around at least a portion of the first area near a corner of the first surface.

The semiconductor chip may include a device layer and an insulation layer, and the friction structure may be formed of a same material as the insulation layer.

The friction structure may be a groove formed in the insulation layer.

The groove may include two straight portions having end portions that meet near the corner of the insulation layer. The groove may include a curved portion.

The friction structure may include a plurality of grooves near each corner of the first surface.

The friction structure may be a barrier formed of the same material as the insulation layer.

The insulation layer may define a region in which the plurality of metal pads are provided and a region defining the barrier.

The barrier may include two straight portions having end portions that meet near the corner of the insulation layer. The barrier may have a curved portion.

The insulation layer may define a region in which the plurality of metal pads are provided and a region defining a plurality of barriers, including the barrier, near each corner of the first surface.

According to a second aspect of present disclosure, a semiconductor package is provided. The semiconductor package includes a top semiconductor chip including a first surface, a plurality of first metal pads provided on the first surface, a plurality of first bumps provided on the plurality of metal pads, and a friction structure provided around at least a portion of the plurality of metal pads near a corner of the first surface, a bottom semiconductor chip including an upper surface, a plurality of second metal pads provided on the upper surface facing the first surface of the top semiconductor chip and electrically connected to the plurality of first bumps of the top semiconductor chip, a through-silicon via TSV electrically connected to at least some of the plurality of second metal pads, a plurality of third metal pads provided on a lower surface opposite to the upper surface, and a plurality of second bumps provided on the plurality of third metal pads, and a non-conductive film material in a space between the top semiconductor chip and the bottom semiconductor chip.

The top semiconductor chip may include a device layer and a first redistribution layer, and the friction structure may be formed of a same material as the first redistribution layer.

The friction structure may be a groove, and a portion of the non-conductive film material may be disposed in the groove.

The friction structure may be a barrier, a portion of the non-conductive film material surrounds the barrier.

The bottom semiconductor chip may include a device layer and a second redistribution layer provided on the upper surface, a trench in the second redistribution layer, wherein the trench may be disposed along at least a lateral side of the top semiconductor chip around a region to which the top semiconductor chip is attached, and a portion of the non-conductive film material may be disposed in the trench.

The bottom semiconductor chip may include a device layer and a second redistribution layer provided on the upper surface, and a portion of the second redistribution layer may form a bar, wherein the bar may be disposed along at least a lateral side of the top semiconductor chip around a region to which the top semiconductor chip is attached, and the non-conductive film material may be disposed internal to the bar at a later side of the top semiconductor chip.

The semiconductor package may further include a mold material configured to cover a side surface of the top semiconductor chip and an upper surface of the bottom semiconductor chip, a package substrate attached to a lower surface of the bottom semiconductor chip, an under-fill disposed between the bottom semiconductor chip and the package substrate, and a plurality of third bumps provided on a lower surface of the package substrate.

According to a third aspect of present disclosure, a manufacturing method of a semiconductor package is provided. The manufacturing method of a semiconductor package includes providing a first redistribution layer on a first surface of a top semiconductor chip, where the redistribution layer may include at least one of a groove or a barrier near a corner of the first surface, providing a plurality of bumps on the redistribution layer, disposing a non-conductive film material on the first surface, aligning the first surface of the top semiconductor chip to face an upper surface of a bottom semiconductor chip, heating and pressing the top semiconductor chip toward the bottom semiconductor chip, melting the non-conductive film material and electrically connecting the plurality of bumps to metal pads provided on an upper surface of the bottom semiconductor chip, and covering a side surface of the top semiconductor chip and the upper surface of the bottom semiconductor chip in a mold material.

The manufacturing method may further include providing a second redistribution layer on the upper surface of the bottom semiconductor chip, and forming at least one of a trench or a bar in the second redistribution layer and provided along at least a lateral side of the top semiconductor chip around a region to which the top semiconductor chip is attached.

According to embodiments of the present disclosure, shrinkage of a non-conductive film material away from corners of a semiconductor chip may be suppressed by providing a friction structure on a surface of the semiconductor chip, and thereby the non-conductive film material may fill an entire attachment region between two semiconductor chips. In particular, since the friction structure may be provided near a corner of a surface of the semiconductor chip, the shrinkage of the non-conductive film material near corner may be suppressed.

### BRIEF DESCRIPTION OF THE DRAWINGS

FIG. 1A, FIG. 1B, and FIG. 1C show a conventional 3D packaging process for attaching two semiconductor chips.

FIG. 2A, FIG. 2B, FIG. 2C, and FIG. 2D show a planar change of a non-conductive film material during a process of attaching two semiconductor chips.

FIG. 3 shows a surface of a top semiconductor chip provided with a groove as a friction structure according to an embodiment of the present disclosure.

FIG. 4 shows a surface of a top semiconductor chip provided with a barrier as a friction structure according to another embodiment of the present disclosure.

FIG. 5A, FIG. 5B, FIG. 5C, and FIG. 5D shows various arrangements of a groove according to embodiments of the present disclosure.

FIG. 6A, FIG. 6B, FIG. 6C, and FIG. 6D shows various arrangements of a barrier according to embodiments of the present disclosure.

FIG. 7 schematically shows a cross-sectional view of a semiconductor chip according to an embodiment of the present disclosure.

FIG. 8 schematically shows a cross-sectional view of a semiconductor chip according to another embodiment of the present disclosure.

FIG. 9 schematically shows a cross-sectional view of a semiconductor package according to an embodiment of the present disclosure.

FIG. 10 shows a surface of a bottom semiconductor chip according to an embodiment of the present disclosure.

FIG. 11 schematically shows a cross-sectional view of a semiconductor package according to another embodiment of the present disclosure.

FIG. 12 schematically shows a cross-sectional view of a semiconductor package according to still another embodiment of the present disclosure.

FIG. 13 schematically shows a cross-sectional view of a top semiconductor chip according to still another embodiment of the present disclosure.

FIG. 14 schematically shows a cross-sectional view of a semiconductor package according to still another embodiment of the present disclosure.

FIG. 15A, FIG. 15B, FIG. 15C, FIG. 15D, FIG. 15E, FIG. 15F, FIG. 15G, and FIG. 15H show a manufacturing process of a semiconductor package according to an embodiment of the present disclosure.

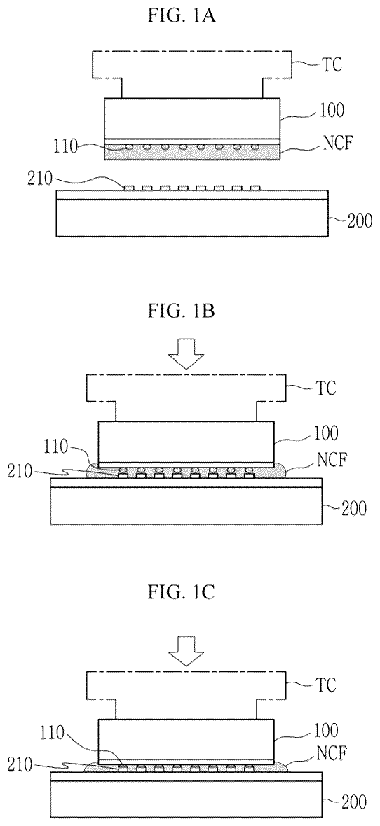

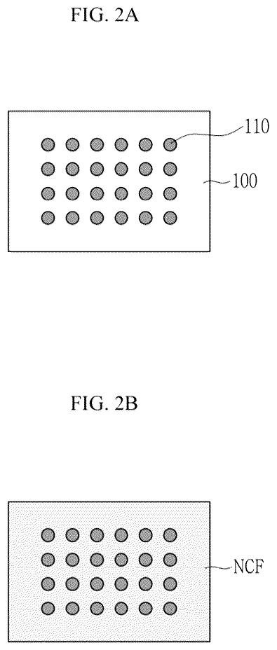

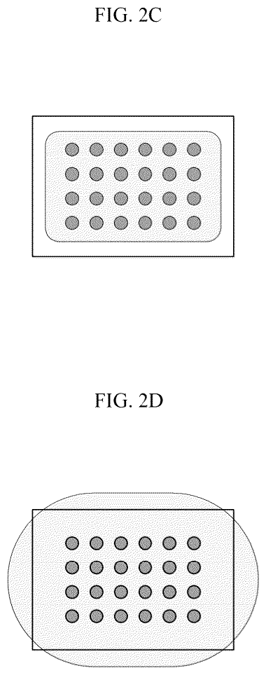

### DETAILED DESCRIPTION

The present disclosure will be described more fully hereinafter with reference to the accompanying drawings, in which embodiments of the disclosure are shown. As those skilled in the art would realize, embodiments may be modified in various different ways, all without departing from the spirit or scope of the present disclosure.

In order to clearly describe the present disclosure, parts or portions that are irrelevant to the description may be omitted, and identical or similar constituent elements throughout the specification are denoted by the same reference numerals.

Further, in the drawings, the size and thickness of each element may be arbitrarily illustrated for ease of description, and the present disclosure is not necessarily limited to those illustrated in the drawings. In the drawings, the thicknesses of layers, films, panels, regions, areas, etc., may be exaggerated for clarity. In the drawings, for ease of description, the thicknesses layers and areas may be exaggerated.

In addition, in the drawing, bumps, metal pads, and vias may be enlarged and exaggerated compared to other elements to better show their structures.

It will be understood that when an element such as a layer, film, region, area or substrate is referred to as being “on” or “above” another element, it can be directly on the other element or intervening elements may also be present. In contrast, when an element is referred to as being “directly on” another element, there are no intervening elements present. Further, in the specification, the word “on” or “above” means disposed on or below the object portion, and does not necessarily mean disposed on an upper side of an object portion based on a gravitational direction.

In addition, unless explicitly described to the contrary, the word “include” and variations such as “includes” or “including” will be understood to imply the inclusion of stated elements and not the exclusion of any other elements.

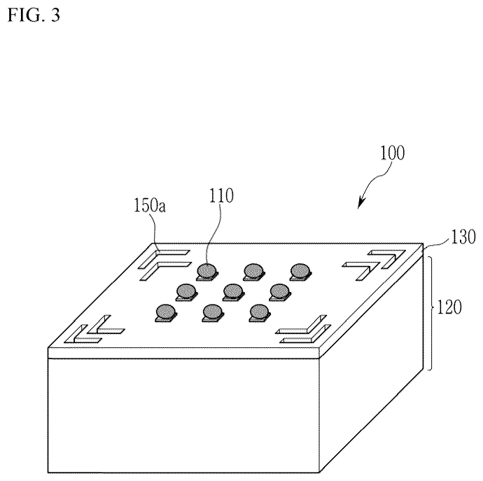

FIG. 3 shows a surface of a top semiconductor chip having a friction structure according to an embodiment of the present disclosure. The friction structure may be a groove according to an embodiment of the present disclosure.

A top semiconductor chip 100 may include a device layer 120 and an insulation layer 130. Semiconductor elements such as transistors may be implemented in the device layer 120. The insulation layer 130 may be a passivation layer, an oxide layer, a dielectric layer, or the like, but is not limited thereto. A plurality of metal pads may be exposed on a surface of the insulation layer 130, and a plurality of bumps 110 may be provided on the plurality of metal pads. The plurality of bumps 110 may be bonded to the metal pads provided on the surface of the bottom semiconductor chip. For example, the plurality of bumps 110 may be bonded to the metal pads provided on the surface of the bottom semiconductor chip by a process such as reflow soldering.

In an embodiment, a groove 150a may be provided near a corner of the insulation layer 130. For example, a plurality of grooves 150a may be provided near corners of the insulation layer 130. The groove 150a is an example of a friction structure. The groove 150a may be a depression in the insulation layer 130.

The groove 150a may include two straight portions having end portions that meet near the corner of the insulation layer 130. The end portions of the straight portions of the groove 150a may perpendicularly meet near the corner of the insulation layer 130. For example, the groove 150a may have a chevron shape. The shape of the groove 150a is not limited.

The groove 150a may function as a friction structure. The friction structure may suppress a contraction of a non-conductive film material NCF. For example, the friction structure may suppress a contraction of the non-conductive film material NCF when the conductive film material NCF attached to a surface of the top semiconductor chip 100 shrinks due to heating. Accordingly, the groove 150a may have various shapes.

In the example illustrated in FIG. 3, two grooves 150a may be provided as a pair of grooves near each corner, for example. In an embodiment, the grooves 150a may be arranged in parallel. In an example in which more than one groove 150a is provided and the grooves 150a are arranged in parallel, the grooves 150a may have a same length or different lengths. While FIG. 3 illustrates two grooves 150, three, four, or more grooves 150a may be provided near a corner. Additional grooves 150a may provide additional friction.

The non-conductive film material NCF may be attached to a surface of the top semiconductor chip 100 of an embodiment, the top semiconductor chip 100 may be aligned on the bottom semiconductor chip, and heat and pressure may be applied to the top semiconductor chip 100. As the heat and pressure are applied to the top semiconductor chip 100, a portion of the non-conductive film material NCF may be prevented from shrinking to a center of the insulation layer 130 by entering the groove 150a or being caught by an edge of the groove 150a, near the corners.

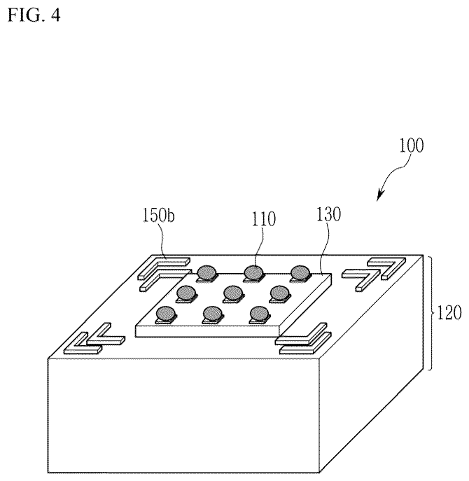

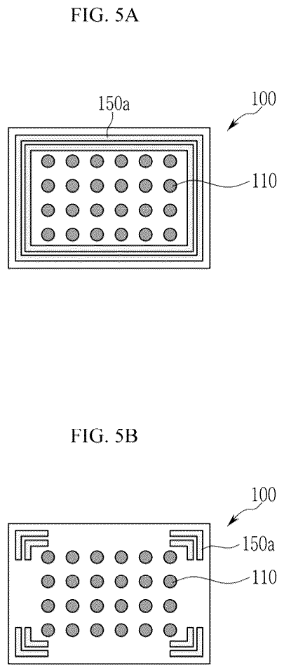

FIG. 4 shows a surface of a top semiconductor chip including a friction structure according to another embodiment of the present disclosure. The friction structure may be a barrier according to an embodiment of the present disclosure.

The top semiconductor chip 100 may include the device layer 120 and the insulation layer 130. The plurality of metal pads may be exposed on a surface of the insulation layer 130, and the plurality of bumps 110 may be provided on the plurality of metal pads. The insulation layer 130 may cover a portion of a first surface of the top semiconductor chip 100. The insulation layer 130 may not entirely cover a first surface of the top semiconductor chip 100.

The insulation layer 130 may be provided in a region where the plurality of bumps 110 are provided. The insulation layer 130 may include a redistribution layer that electrically connects semiconductor elements of the device layer 120 and the plurality of metal pads. A plurality of barriers 150b may be provided near a corner of the first surface of the top semiconductor chip 100.

The plurality of barriers 150b may be formed of a same material as the insulation layer 130. For example, the insulation layer 130 may be formed on a portion of the first surface of the top semiconductor chip 100, and the insulation layer 130 may be patterned to form the plurality of barriers 150b. In an example in which the barrier 150b may be formed by patterning the insulation layer 130, the barrier 150b may extend from the first surface of the top semiconductor chip 100.

As shown, the plurality of barriers 150b may be created by removing a portion of the insulation layer 130 in areas near to the corners of the of the first surface of the top semiconductor chip 100. The barrier 150b may have various shapes. For example, the barrier 150b may be formed with a shape like the groove 150a described herein. Irregular edges or additional corners create additional friction.

The non-conductive film material NCF may be attached to a surface of the top semiconductor chip 100, the top semiconductor chip 100 may be aligned on the bottom semiconductor chip, and heat and pressure may be applied to the top semiconductor chip 100. As the heat and pressure are applied to the top semiconductor chip 100, the portion of the non-conductive film material NCF may surround the barrier 150b near the corners. For example, the non-conductive film material NCF may surround the barrier 150b near the corners and the barrier 150b may prevent the non-conductive film material NCF from shrinking toward the center. For example, the non-conductive film material NCF may surround the barrier 150b near the corners and the barrier 150b may prevent the non-conductive film material NCF from shrinking toward the center and the insulation layer 130.

The friction structure may be a structure having edges and/or vertices that may not be parallel to a direction in which the non-conductive film material NCF may slide to shrink. The friction structures may have various shapes other than grooves or barriers.

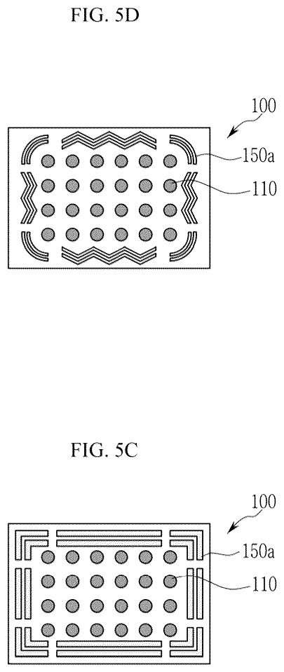

FIG. 5A, FIG. 5B, FIG. 5C, and FIG. 5D show various arrangements of a groove according to embodiments of the present disclosure. According to an embodiment, two or more grooves may be formed in parallel.

Referring to FIG. 5A, the groove 150a may be continuously formed on the first surface of the top semiconductor chip 100 to surround the plurality of bumps 110. For example, the groove 150a may be formed on the first surface of the top semiconductor chip 100 along a lateral side of the top semiconductor chip 100 and surrounding the plurality of bumps 110. Referring to FIG. 5B, the groove 150a may be formed near the corner. For example, the groove 150a may be formed near the corner, and not formed along portions of the lateral side of the top semiconductor chip 100. Referring to FIG. 5C, the groove 150a may be discontinuously formed to surround the plurality of bumps 110. For example, first portions of the groove 150a may be formed near the corner, and second portions of the groove 150a may be separately formed along portions of the lateral side of the top semiconductor chip 100. A gap may be formed between the first portions of the groove 150a near the corner and the second portions of the groove 150a formed along portions of the lateral side of the top semiconductor chip 100. Referring to FIG. 5D, the groove 150a may have a curved portion or a zigzag shaped portion. For example, the first portions of the groove 150a formed near the corner may have a curved shape, and the second portions of the groove 150a may be separately formed along portions of the lateral side of the top semiconductor chip 100 and have a zigzag shape.

Although FIGS. 5A-D show patterns of various grooves 150a as examples, the present disclosure is not limited to these examples. For example, it may also be possible to form the plurality of grooves 150a in the form of a dotted line. In some embodiments, the grooves 150a may have a same depth or may have different depths.

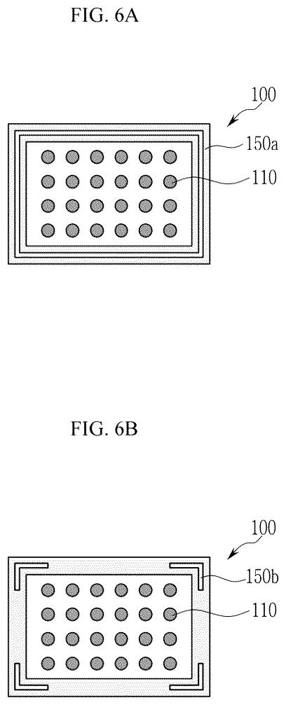

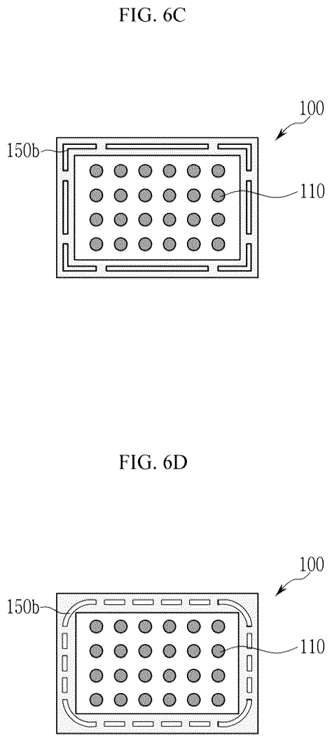

FIG. 6A, FIG. 6B, FIG. 6C, and FIG. 6D show various arrangements of a barrier according to embodiments of the present disclosure. According to an embodiment, two or more barriers may be formed in parallel.

The barrier 150b may be formed by partially removing the insulation layer. For example, a portion of the insulation layer may be removed in a region at an edge portion of the top semiconductor chip 100, wherein the insulation layer of the region other than the barrier 150b is removed. Further, a region of the insulation layer at a center of the top semiconductor chip 100 may not be removed. For example, a region of the insulation layer may remain to support the plurality of bumps 110.

Referring to FIG. 6A, the barrier 150b has a shape of a continuous rectangular frame. For example, the barrier 150b may be formed on the first surface of the top semiconductor chip 100 along the lateral side of the top semiconductor chip 100 and surrounding the plurality of bumps 110. Referring to FIG. 6B, each barrier 150b may have two straight portions that meet near a corner. The end portions of the straight portions of the groove 150a may perpendicularly meet near the corner of the insulation layer 130. The barrier 150b may be formed near the corner, and not formed along portions of the lateral side of the top semiconductor chip 100. Referring to FIG. 6C, the barrier 150b is formed not only near the corners but also along lateral sides. For example, first portions of the barrier 150b may be formed near the corner, and second portions of the barrier 150b may be separately formed along portions of the lateral side of the top semiconductor chip 100. A gap may be formed between the first portions of the barrier 150b near the corner and the second portions of the barrier 150b formed along portions of the lateral side of the top semiconductor chip 100. Referring to FIG. 6D, the barrier 150b near the corner may have a curved portion, and the barrier 150b on the lateral side may have a shape such as a dotted line.

Although FIGS. 6A-D show one row of barriers 150b, it should be understood that two or more rows of barriers 150b may be used. Also, similar to the groove 150a shown in FIG. 5D, the barrier 150b may have a zigzag shape or a curved shape. Further, in an example in which more than one barrier 150b is provided and the barriers 150b are arranged in parallel, the barriers 150b may have a same length or different lengths.

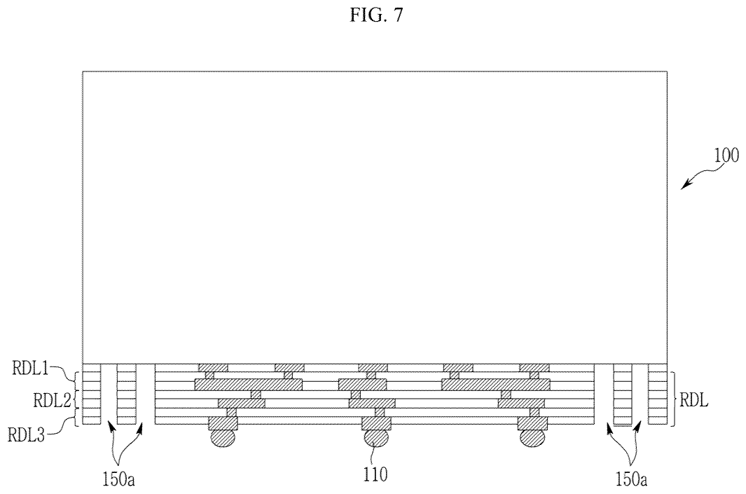

FIG. 7 schematically shows a cross-sectional view of a semiconductor chip according to an embodiment of the present disclosure.

The top semiconductor chip 100 may include a redistribution layer RDL on the first surface. The redistribution layer RDL may be deposited including a sub-redistribution layer. For example, the redistribution layer RDL may include a first sub layer RDL1, a second sub layer RDL2, and a third sub layer RDL3. Each sub-redistribution layer may include a via layer and a pad layer. For example, the first sub layer RDL1 may include a via layer and a pad layer, the second sub layer RDL2 may include a via layer and a pad layer, and the third sub layer RDL3 may include a via layer and a pad layer. Metal pads may be exposed on a surface of the third sub layer RDL3, and bumps 110 may be disposed on the metal pads.

In a photolithography and etching process for stacking each of the first sub layer RDL1, the second sub layer RDL2, and the third sub layer RDL3, the grooves 150a may be formed together with the redistribution layer by using a photomask having a pattern corresponding to the grooves 150a. The grooves 150a may be created by removing a dielectric layer in regions corresponding to the grooves. Although not limiting, when each redistribution layer includes a via layer and a pad layer, a pattern corresponding to the groove 150a may be included in a photomask for patterning the via layers and the pad layers.

A planar structure of the groove 150a may be, for example, one of the patterns illustrated in FIGS. 5A-D, but is not limited thereto.

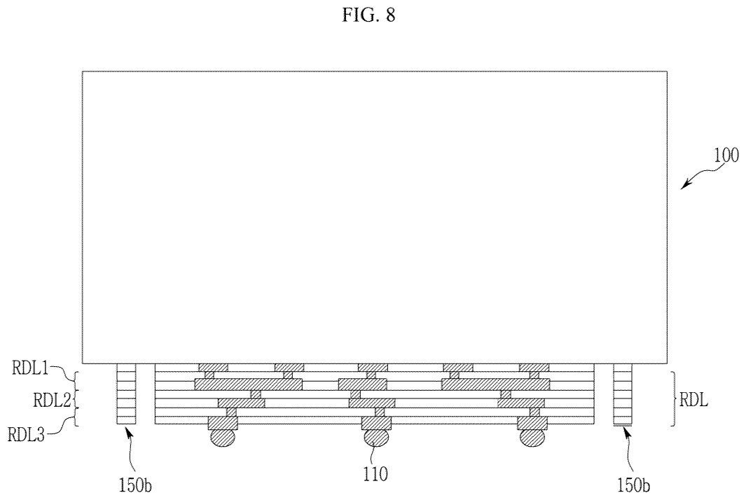

FIG. 8 schematically shows a cross-sectional view of a semiconductor chip according to another embodiment of the present disclosure.

In an embodiment, the top semiconductor chip 100 includes the redistribution layer RDL, and the redistribution layer RDL includes first sub layer RDL1, the second sub layer RDL2, and the third sub layer RDL3. Barriers 150b may be provided in the redistribution layer RDL as frictional structures.

In a photolithography and etching process the redistribution layer RDL may be deposited including a sub-redistribution layer. For example, the redistribution layer RDL may be deposited including the first sub layer RDL1, the second sub layer RDL2, and the third sub layer RDL3. The barrier 150b may be formed by removing a portion of the redistribution layer RDL around the barrier 150b using a photomask. In an embodiment, the barrier 150b may be created by partially removing a dielectric layer forming the redistribution layer RDL.

A planar structure of the barrier 150b may be, for example, one of the patterns illustrated in FIGS. 6A-D, but is not limited thereto.

In the examples of FIG. 7 and FIG. 8, the redistribution layer RDL includes three sub layers, but those skilled in the art will understand that the number of sub-redistribution layers is not limited.

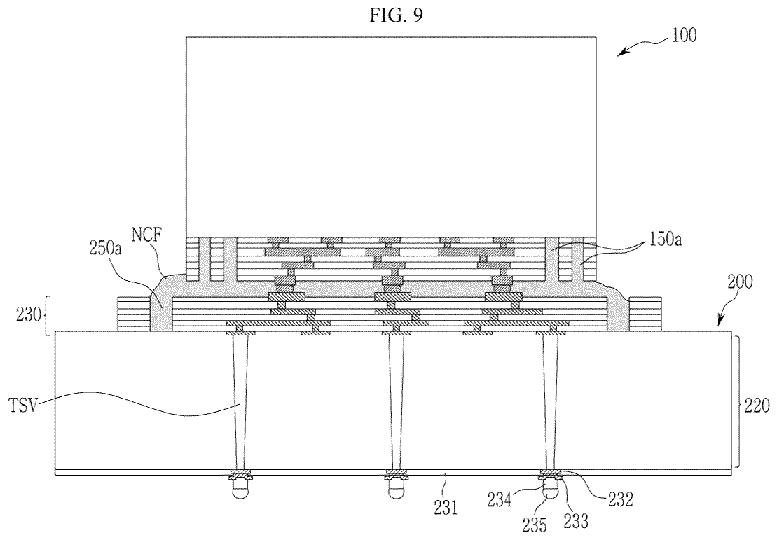

FIG. 9 schematically shows a cross-sectional view of a semiconductor package according to an embodiment of the present disclosure.

The semiconductor package may include the top semiconductor chip 100 and a bottom semiconductor chip 200. The top semiconductor chip 100 may be the top semiconductor chip shown in FIG. 7. The top semiconductor chip 100 may have two rows of grooves 150a provided in the redistribution layer. While the semiconductor package is illustrated including the top semiconductor chip shown in FIG. 7, the top semiconductor chip 100 may be the top semiconductor chip shown in FIG. 8.

The bottom semiconductor chip 200 may include an insulation layer 230. The insulation layer 230 may be formed on an upper surface of a device layer 220. A passivation layer 231 may be formed on a lower surface of the device layer 220 opposite the upper surface of the device layer 220. In an embodiment, the insulation layer 230 is a redistribution layer, but is not limited thereto.

The device layer 220 may include a through-silicon via TSV. The device layer 220 may include a plurality of through-silicon vias TSVs. Metal pads 232 may penetrate and be exposed through the passivation layer 231. Under bump metallurgies UBM 233 may be provided on the metal pads 232. Cu pillars 234 and bumps 235 may be sequentially disposed on the under bump metallurgies UBM 233. In an embodiment, although the Cu pillars 234 and the bumps 235 are disclosed, the bumps 235 may be disposed directly on the under bump metallurgies UBM 233.

The insulation layer 230 of the bottom semiconductor chip 200 may include a trench 250a. The trench 250a may be disposed along a periphery of a region where the top semiconductor chip 100 may be attached on an upper surface of the bottom semiconductor chip 200. For example, the trench 250a may be disposed continuously around the region where the top semiconductor chip 100 may be attached on an upper surface of the bottom semiconductor chip 200. The trench 250a may be disposed along at least a lateral side of the top semiconductor chip 100.

A portion of the non-conductive film material NCF may be disposed within the trench 250a. While attaching the top semiconductor chip 100 and the bottom semiconductor chip 200, the non-conductive film material NCF may fill in a space between the top semiconductor chip 100 and the bottom semiconductor chip 200. A portion of the non-conductive film material NCF may be disposed within the groove 150a of the top semiconductor chip 100. Also, a portion of the non-conductive film material NCF may be pushed out of the periphery of the top semiconductor chip 100 and introduced into the trench 250a. The trench 250a may serve to block the non-conductive film material NCF from spreading further around the lateral side of the top semiconductor chip 100. By this, the non-conductive film material NCF may be induced to expand toward a corner of the top semiconductor chip 100.

In an embodiment, the groove 150a (or barrier 150b) of the top semiconductor chip 100 and the trench 250a of the bottom semiconductor chip 200 may promote or ensure a movement of the non-conductive film material NCF into a space at the corner of the top semiconductor chip 100 on the bottom semiconductor chip 200. Accordingly, the space at the corner may be sufficiently filled in a vicinity of the corner of the top semiconductor chip 100.

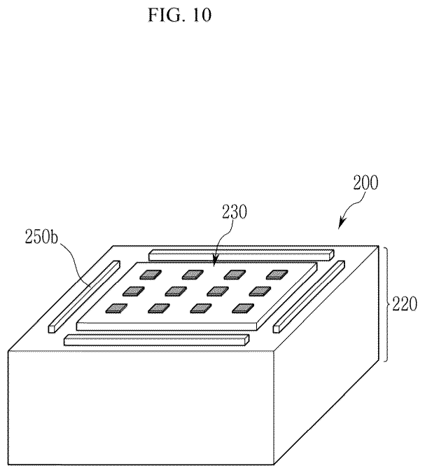

FIG. 10 shows a surface of a bottom semiconductor chip according to an embodiment of the present disclosure.

Referring to FIG. 9 and FIG. 10, the bottom semiconductor chip 200 may include the trench 250a disposed around portions of the region where the top semiconductor chip 100 may be attached on an upper surface of the bottom semiconductor chip 200. For example, the trench 250a may be formed between a bar 250b and the insulation layer 230. In an embodiment, the trench 250a and the bar 250b may be formed by partially removing an insulation layer 230.

The insulation layer 230 may be patterned and remaining portions of the insulation layer 230 may include a region to which the top semiconductor chip may be attached to the device layer 220 and a region forming the bar 250b. The bar 250b may be disposed on a lateral side of the region to which the top semiconductor chip may be attached to the device layer 220 The bar 250b may impede or block a movement of the non-conductive film material NCF from spreading further sideways. For example, the non-conductive film material NCF may be disposed internal to the bar 250b at a later side of the top semiconductor chip 100.

Both the trench 250a and the bar 250b may be formed in a process of forming the insulation layer 230. For example, the insulation layer 230 may be a redistribution layer, and the trench 250a or the bar 250b may be formed by using a photomask having a corresponding pattern in a photolithography and etching process. The trench 250a may be created by removing a portion of the insulation layer 230 in the corresponding region, and the bar 250b may be created by removing the insulation layer around a corresponding region of the bar 250b.

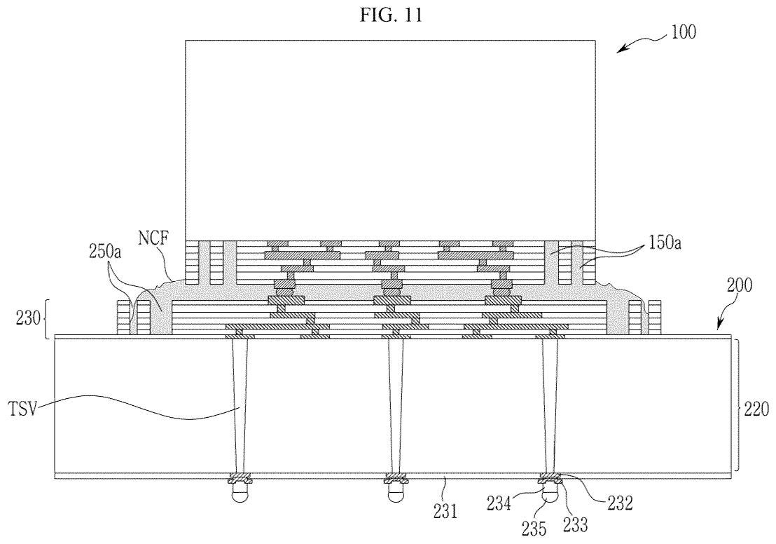

FIG. 11 schematically shows a cross-sectional view of a semiconductor package according to another embodiment of the present disclosure.

Trenches 250a may be arranged in rows on the upper surface of the bottom semiconductor chip 200. For example, the trenches 250a may be arranged in two rows on the upper surface of the bottom semiconductor chip 200. The rows of trenches 250a may impede or block a spreading of the non-conductive film material NCF. For example, an outer trench of the trenches 250a may impede or block the spreading of a portion of the non-conductive film material NCF extending over an inner trench of the trenches 250a.

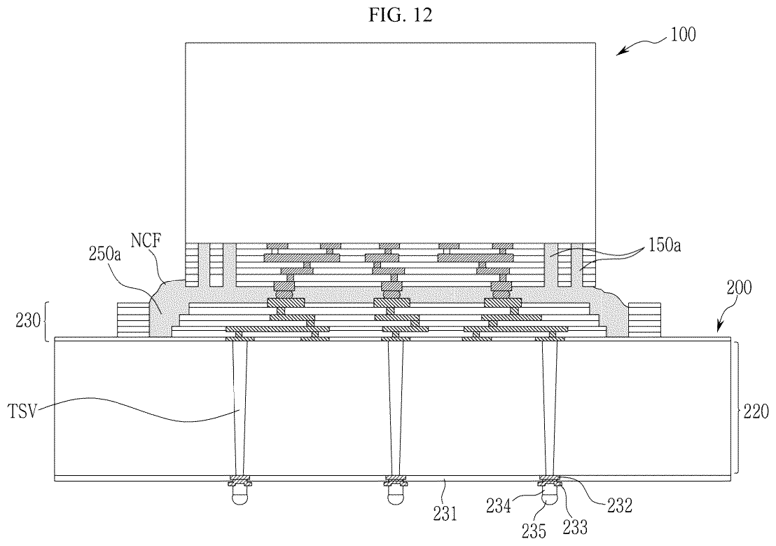

FIG. 12 schematically shows a cross-sectional view of a semiconductor package according to still another embodiment of the present disclosure.

In an embodiment, the trench 250a may be provided on the upper surface of the bottom semiconductor chip 200. An inner sidewall of the trench 250a may have a generally stepped shape. Since other elements other than the structure of the trench 250a may be the same as those illustrated in FIG. 10, these elements may not be further described.

In an embodiment, the trench 250a may be defined by an outer sidewall and an inner sidewall, and a distance between the outer sidewall and the inner sidewall may be greater at an upper end than at a lower end of the trench 250a along a depth direction. In an embodiment, the outer sidewall may be standing upright and the inner sidewall may have a stepped shape. That is, the outer sidewall may be linear or flat along the depth direction and the inner sidewall may have a stepped shape. In another embodiment, the inner sidewall may be sloped or wavy in shape and a distance between the outer sidewall and the inner sidewall may be greater at an upper end than at a lower end of the trench 250a along a depth direction.

The non-conductive film material NCF in a gel state may flow into the trench 250a along a generally inclined inner sidewall and may be reliably blocked by the outer sidewall standing upright. The generally inclined inner sidewall of the trench 250a may suppress or prevent a void from being form at a bottom portion of the trench 250a, which may be formed in a case where the inner sidewall is standing upright. When the inner sidewall has a stepped shape or an inclined surface, the formation voids inside the bottom of the trench may be suppressed or prevented.

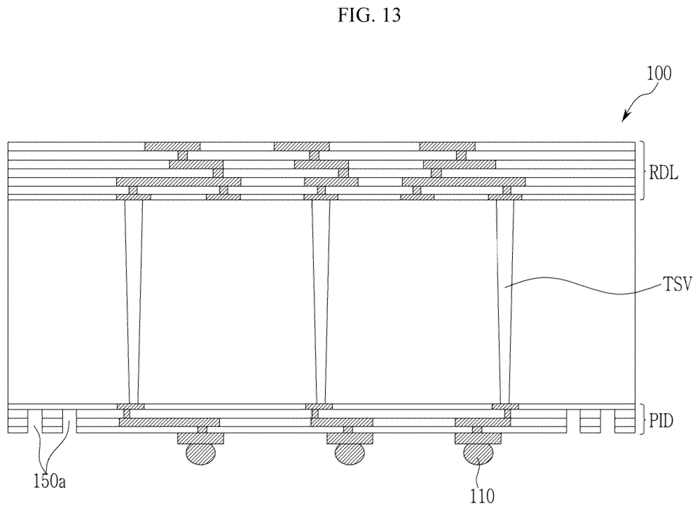

FIG. 13 schematically shows a cross-sectional view of a top semiconductor chip according to still another embodiment of the present disclosure.

In some embodiments, the top semiconductor chip 100 includes the redistribution layer RDL, and the groove 150a or the barrier 150b may be formed in the redistribution layer RDL. In an embodiment, the top semiconductor chip 100 may include the redistribution layer RDL on a surface and a photo imagable dielectric layer PID on another surface, and the groove 150a may be created by the photo imagable dielectric layer PID.

In an embodiment, the top semiconductor chip 100 may include the through-silicon vias TSVs. The redistribution layer RDL and the photo imagable dielectric layer PID may have vias and pads, respectively, and at least some of the vias and pads may be electrically connected by the through-silicon vias TSVs. The bumps 110 may be disposed on a surface of the photo imagable dielectric layer PID, and the top semiconductor chip 100 may be electrically attached to the bottom semiconductor chip through the bumps 110. For chip attachment, a non-conductive film material NCF may be attached to cover at least a portion of the photo imagable dielectric layer PID. When heat and pressure are applied during the attachment process, a shrinking of the non-conductive film material NCF may be suppressed by the groove 150a disposed in the photo imagable dielectric layer PID, and a spreading of the non-conductive film material to the lateral side may be suppressed or prevented by the trench of the bottom semiconductor chip (not shown). Accordingly, the non-conductive film material NCF may sufficiently fill an area near the corner of the top semiconductor chip 100.

Although the groove 150a may be formed by the photo imagable dielectric layer PID, a barrier may be formed. Also, the grooves and barriers may have various patterns illustrated in FIGS. 5A-D and FIGS. 6A-D, for example.

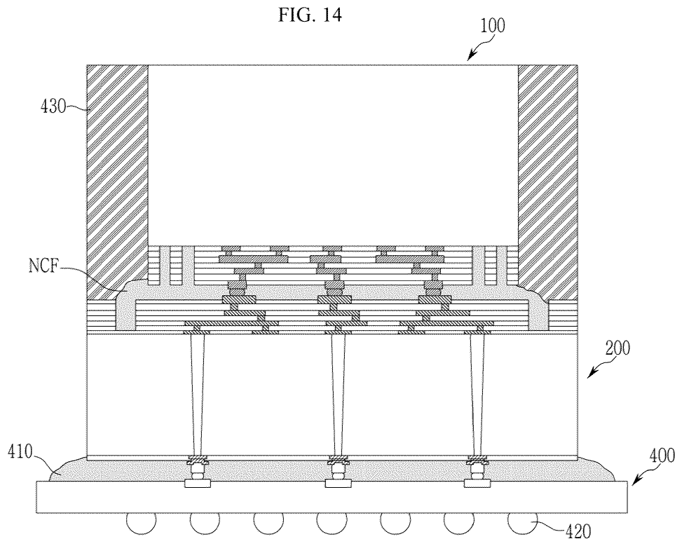

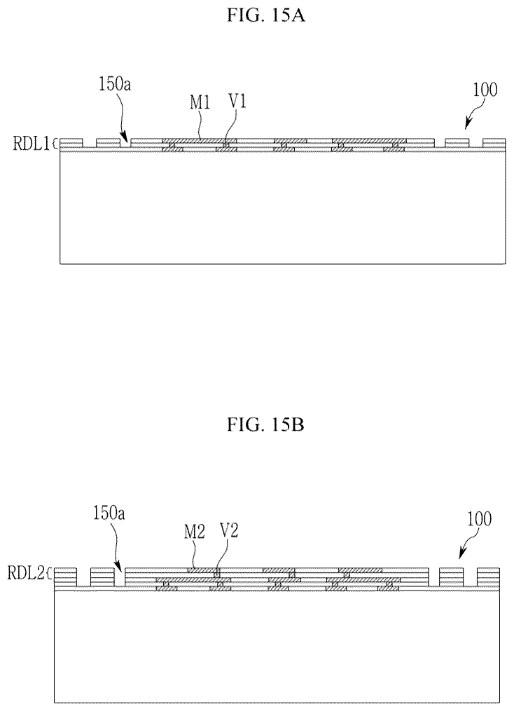

FIG. 14 schematically shows a cross-sectional view of a semiconductor package according to still another embodiment of the present disclosure. The semiconductor package may include the top semiconductor chip 100, the bottom semiconductor chip 200, and a package substrate 400.

The top semiconductor chip 100 may include the redistribution layer on a lower surface, and the redistribution layer may include grooves. However, the top semiconductor chip 100 may be the top semiconductor chip shown in FIG. 7, FIG. 8, or FIG. 12. Also, the groove may have various patterns illustrated in FIGS. 5A-D, for example. Barriers may be disposed instead of grooves, and the barriers may have various patterns illustrated in FIGS. 6A-D, for example.

The bottom semiconductor chip 200 may include a redistribution layer on the upper surface, and the redistribution layer may include a trench. However, the bottom semiconductor chip 200 may be the bottom semiconductor chip shown in FIG. 9, FIG. 10, FIG. 11, or FIG. 12.

The plurality of bumps may be electrically connected the top semiconductor chip 100 and the bottom semiconductor chip 200, and a space may be filled with the non-conductive film material NCF. A space around the plurality of bumps may be filled with the non-conductive film material NCF. A portion of the non-conductive film material NCF may spread out around the top semiconductor chip 100 and may be disposed in the trench of the bottom semiconductor chip 200. A portion of the non-conductive film material NCF may be disposed in the groove of the top semiconductor chip 100.

The side surfaces of the top semiconductor chip 100 and the upper surface of the bottom semiconductor chip 200 may be covered by a mold material 430. The mold material 430 may increase adhesion between the top semiconductor chip 100 and the bottom semiconductor chip 200. The mold material 430 may protect the structures. In FIG. 14, the mold material 430 is shown to cover side surfaces of the top semiconductor chip 100. The mold material 430 may selectively cover an upper surface of the top semiconductor chip 100 as well.

A lower surface of the bottom semiconductor chip 200 may be mounted on the package substrate 400 by the plurality of bumps. A space between the bottom semiconductor chip 200 and the package substrate 400 may be filled by an underfill 410. The underfill 410 may enhance a bonding strength between the bottom semiconductor chip 200 and a package substrate 400. The underfill 410 may protect the bumps electrically connecting the bottom semiconductor chip 200 and a package substrate 400.

A plurality of bumps 420 may be disposed on a lower surface of the package substrate 400. Although not shown, the package substrate 400 may be mounted on another system board or the like through the plurality of bumps 420.

Although the semiconductor package may have a structure in which the top semiconductor chip 100 is mounted on the bottom semiconductor chip 200, it is also possible to attach an additional semiconductor chip on the top semiconductor chip 100. For example, a third semiconductor chip may be attached on the upper surface of the top semiconductor chip 100.

In some embodiments, a redistribution layer RDL or a photo imagable dielectric PID layer may be provided on the upper surface of the top semiconductor chip. For example, trenches or bars may be provided in the redistribution layer RDL or the photo imagable dielectric layer on the upper surface of the top semiconductor chip of FIG. 12, and grooves or barriers may be provided in a lower surface of the third semiconductor chip attached to the upper surface of the top semiconductor chip.

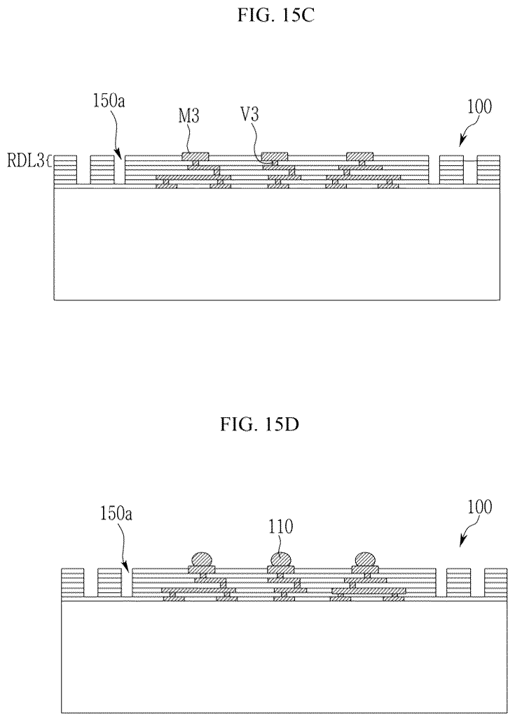

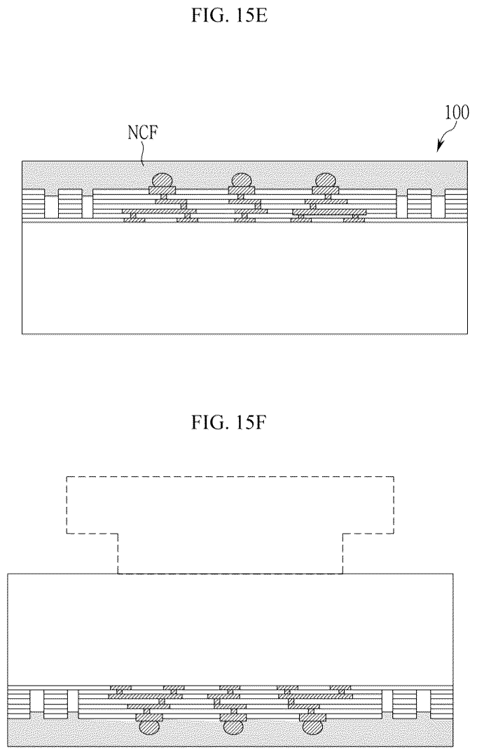

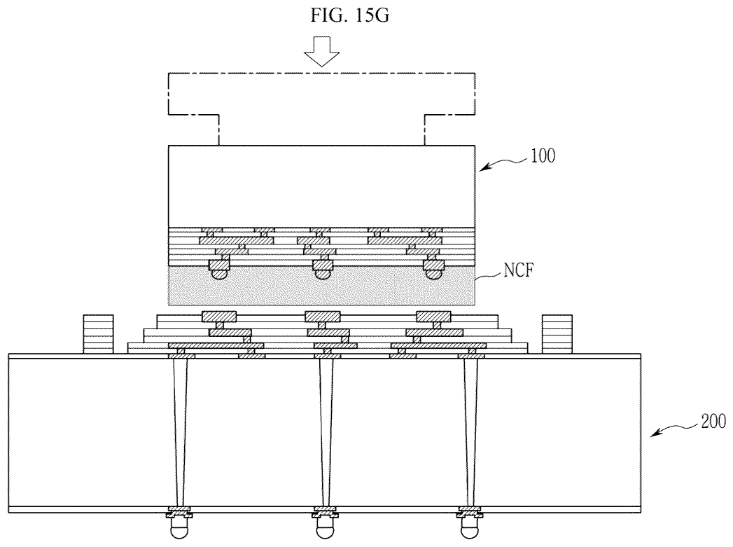

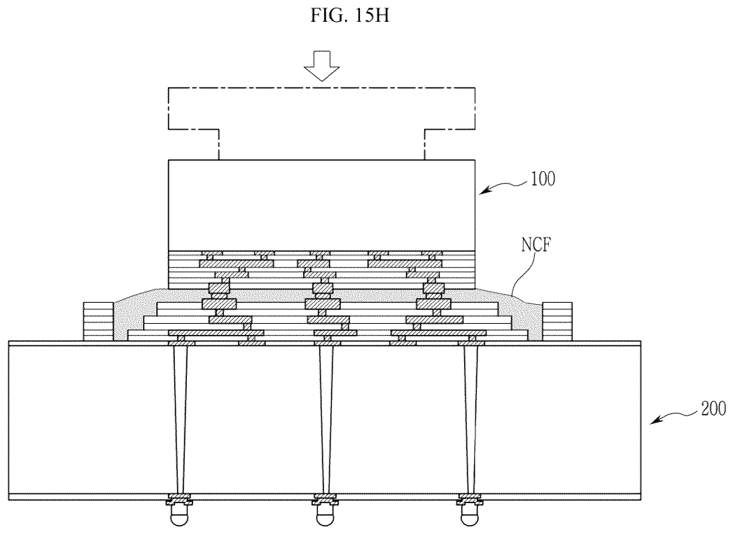

FIG. 15A, FIG. 15B, FIG. 15C, FIG. 15D, FIG. 15E, and FIG. 15F show a manufacturing process of a semiconductor package according to an embodiment of the present disclosure.

Referring to FIG. 15A, the first redistribution sub layer RDL1 may be stacked on a lower surface of the top semiconductor chip 100. The first redistribution sub layer may include a via layer defining the via V1 and a pad layer defining the pad P1. A photomask having a pattern for forming the via V1 and the pad P1 may including a pattern for forming the groove 150a. When a portion of the first redistribution sub layer RDL1 is removed by the photolithography and etching process for the via V1 and the pad P1, a portion of the first redistribution sub layer RDL1 corresponding to the groove 150a may also be removed.

As illustrated in FIG. 15A, the groove 150a may not penetrate one or more lower layers on the top semiconductor chip 100. The lower layer may be formed directly on the top semiconductor chip 100. The lower layer may be a layer deposited and patterned before the first redistribution sub layer RDL1 is deposited. The lower layer may include a via for electrically connecting the vias V1 to the top semiconductor chip 100.

Referring to FIG. 15B, the second redistribution sub layer RDL2 may be stacked on the first redistribution sub layer RDL1. The second redistribution sub layer may include a via layer defining a via V2 and a pad layer defining a pad P2. A pattern corresponding to the groove 150a may be included in a photomask for forming the via V2 and the pad P2, and the groove 150a may be formed in the second redistribution sub layer RDL2 by removing a portion of the second redistribution sub layer RDL2 corresponding to the groove 150a.

Referring to FIG. 15C, the third redistribution sub layer RDL3 may be stacked on the second redistribution sub layer RDL2. The third redistribution sub layer may include a via layer defining a via V3 and a pad layer defining a pad P3. A process of creating the groove 150a may be the same as that of the first redistribution sub layer RDL1 and the second redistribution sub layer RDL2. That is, a pattern corresponding to the groove 150a may be included in a photomask for forming the via V3 and the pad P3, and the groove 150a may be formed in the third redistribution sub layer RDL3 by removing a portion of the third redistribution sub layer RDL3 corresponding to the groove 150a.

Referring to FIG. 15D, the plurality of bumps may be disposed on the pads exposed on the surface of the third redistribution sub layer RDL3.

In FIG. 15E, the non-conductive film material may be attached to cover at least a portion of the lower surface of the top semiconductor chip 100.

Referring to FIG. 15F, the top semiconductor chip 100 may be flipped by a thermal compression tool. Referring to FIG. 15G, the lower surface of the top semiconductor chip 100 may face an upper surface of the bottom semiconductor chip 200 and the top semiconductor chip 100 may be aligned with the bottom semiconductor chip 200.

Referring to FIG. 15H, heat and pressure are applied to the non-conductive film material NCF by a thermal compression tool. For example, heat and pressure are applied to the top semiconductor chip 100 and the non-conductive film material NCF. The non-conductive film material NCF may be melted into a gel state, and the plurality of bumps disposed on the lower surface of the top semiconductor chip 100 may penetrate the non-conductive film material NCF. The plurality of bumps disposed on the lower surface of the top semiconductor chip 100 may be electrically connected to the pads disposed on the upper surface of the bottom semiconductor chip 200.

A portion of the non-conductive film material NCF may be disposed in the trench of the bottom semiconductor chip 200, and a portion of the non-conductive film material NCF may be disposed in the groove (not shown) of the top semiconductor chip 100.

Although not shown, thereafter, the semiconductor package of FIG. 14 may be obtained by performing molding with a molding material, grinding the upper surface of the top semiconductor chip 100, mounting the bottom semiconductor chip 200 on the package substrate, and disposing the plurality of bumps on the other side of the package substrate.

Since a method of arranging a plurality of bumps or a reflow process is well known, they are not described in further detail.

While this disclosure has been described in connection with what is presently considered to be practical embodiments, it is to be understood that the disclosure is not limited to disclosed embodiments and is intended to cover various modifications and equivalent arrangements included within the spirit and scope of the appended claims.

### DESCRIPTION OF SYMBOLS

100: top semiconductor chip
110, 235, 420: bump
120, 220: device layer
130, 230: insulation layer
150a: groove
150b: barrier
200: bottom semiconductor chip
210, 233: metal pad
231: passivation layer
233: under bump metallurgy
234: Cu pillar
250a: trench
250b: bar
400: package substrate
410: under-fill
430: mold material

What is claimed is:

1. A semiconductor chip, comprising:
a plurality of metal pads provided on a first surface of the semiconductor chip and defining a first area;
a plurality of bumps provided on the plurality of metal pads; and
a friction structure provided around at least a portion of the first area near a corner of the first surface.

2. The semiconductor chip of claim 1, wherein:
the semiconductor chip comprises a device layer and an insulation layer; and
the friction structure is formed of a same material as the insulation layer.

3. The semiconductor chip of claim 2, wherein the friction structure is a groove formed in the insulation layer.

4. The semiconductor chip of claim 3, wherein the groove comprises two straight portions having end portions that meet near the corner of the insulation layer.

5. The semiconductor chip of claim 3, wherein the groove comprises a curved portion.

6. The semiconductor chip of claim 2, wherein the friction structure comprises a plurality of grooves near each corner of the first surface.

7. The semiconductor chip of claim 2, wherein the friction structure is a barrier formed of the same material as the insulation layer.

8. The semiconductor chip of claim 7, wherein the insulation layer defines a region in which the plurality of metal pads are provided and a region defining the barrier.

9. The semiconductor chip of claim 8, wherein the barrier comprises two straight portions having end portions that meet near the corner of the insulation layer.

10. The semiconductor chip of claim 8, wherein the barrier comprises a curved portion.

11. The semiconductor chip of claim 7, wherein the insulation layer defines a region in which the plurality of metal pads are provided and a region defining a plurality of barriers, including the barrier, near each corner of the first surface.

12. A semiconductor package, comprising:
a top semiconductor chip comprising a first surface, a plurality of first metal pads provided on the first surface, a plurality of first bumps provided on the plurality of first metal pads, and a friction structure provided around at least a portion of the plurality of first metal pads near a corner of the first surface;
a bottom semiconductor chip comprising an upper surface, a plurality of second metal pads provided on the upper surface facing the first surface of the top semiconductor chip and electrically connected to the plurality of first bumps of the top semiconductor chip, a through-silicon via TSV electrically connected to at least some of the plurality of second metal pads, a plurality of third metal pads provided on a lower surface opposite to the upper surface, and a plurality of second bumps provided on the plurality of third metal pads; and
a non-conductive film material in a space between the top semiconductor chip and the bottom semiconductor chip.

13. The semiconductor package of claim 12, wherein:
the top semiconductor chip comprises a device layer and a first redistribution layer; and
the friction structure is formed of a same material as the first redistribution layer.

14. The semiconductor package of claim 13, wherein the friction structure is a groove, and a portion of the non-conductive film material is disposed in the groove.

15. The semiconductor package of claim 13, wherein the friction structure is a barrier, a portion of the non-conductive film material surrounds the barrier.

16. The semiconductor package of claim 12, wherein:
the bottom semiconductor chip comprises a device layer and a second redistribution layer provided on the upper surface;
a trench in the second redistribution layer,
wherein the trench is disposed along at least a lateral side of the top semiconductor chip around a region to which the top semiconductor chip is attached, and
a portion of the non-conductive film material is disposed in the trench.

17. The semiconductor package of claim 12, wherein:
the bottom semiconductor chip comprises a device layer and a second redistribution layer provided on the upper surface; and
a portion of the second redistribution layer forms a bar,
wherein the bar is disposed along at least a lateral side of the top semiconductor chip around a region to which the top semiconductor chip is attached, and
the non-conductive film material is disposed internal to the bar at a later side of the top semiconductor chip.

18. The semiconductor package of claim 12, further comprising:
a mold material configured to cover a side surface of the top semiconductor chip and an upper surface of the bottom semiconductor chip;
a package substrate attached to a lower surface of the bottom semiconductor chip;
an under-fill disposed between the bottom semiconductor chip and the package substrate; and
a plurality of third bumps provided on a lower surface of the package substrate.

19. A manufacturing method of a semiconductor package, comprising:
providing a first redistribution layer on a first surface of a top semiconductor chip, wherein the first redistribution layer includes at least one of a groove or a barrier near a corner of the first surface;
providing a plurality of bumps on the first redistribution layer;
disposing a non-conductive film material on the first surface;
aligning the first surface of the top semiconductor chip to face an upper surface of a bottom semiconductor chip;
heating and pressing the top semiconductor chip toward the bottom semiconductor chip, melting the non-conductive film material and electrically connecting the plurality of bumps to metal pads provided on an upper surface of the bottom semiconductor chip; and
covering a side surface of the top semiconductor chip and the upper surface of the bottom semiconductor chip in a mold material.

20. The manufacturing method of claim 19, further comprising:
providing a second redistribution layer on the upper surface of the bottom semiconductor chip; and
forming at least one of a trench or a bar in the second redistribution layer and provided along at least a lateral side of the top semiconductor chip around a region to which the top semiconductor chip is attached.
